(19) United States
(12) Patent Application Publication
(10) Pub. No.: US 2015/0092132 A1
(43) Pub. Date: Apr. 2, 2015

(54) THIN FILM TRANSISTOR ARRAY PANEL, LIQUID CRYSTAL DISPLAY AND MANUFACTURING METHOD OF THIN FILM TRANSISTOR ARRAY PANEL

(71) Applicant: SAMSUNG DISPLAY CO., LTD., Yongin-City (KR)

(72) Inventors: Jang Mi Kang, Bucheon-si (KR); Se Hyoung Cho, Hwaseong-si (KR); Mee Hye Jung, Suwon-si (KR); Sung Hwan Kim, Yongin-si (KR)

(21) Appl. No.: 14/311,184

(22) Filed: Jun. 20, 2014

(30) Foreign Application Priority Data
Oct. 2, 2013 (KR) 10-2013-0117933

(51) Int. Cl. G02F 1/1362; H01L 27/12; H01L 27/15

(52) U.S. Cl. CPC G02F 1/136286; H01L 27/156; H01L 27/1259; H01L 27/1214; G02F 2001/136218
USPC 349/43; 257/72; 438/34

(57) ABSTRACT

A thin film transistor array panel including a first substrate, a gate conductor on the first substrate, a data conductor on the gate conductor, a shielding electrode on the data conductor and insulated from the data conductor, a passivation layer on the shielding electrode, and a pixel electrode on the passivation layer, in which the shielding electrode includes a vertical portion vertically extending along an edge of a pixel area and overlapped with the data line, and one or more horizontal portions connecting the vertical portions.

### CROSS-REFERENCE TO RELATED APPLICATION

This application claims priority to and the benefit of Korean Patent Application No. 10-2013-0117933 filed in the Korean Intellectual Property Office on Oct. 2, 2013, the entire contents of which are incorporated herein by reference.

### BACKGROUND

1. Field

The present invention relates to a thin film transistor array panel, a liquid crystal display using the same, and a manufacturing method of the thin film transistor array panel.

2. Description of the Related Art

A liquid crystal display which is one of the most common types of flat panel displays currently in use includes two sheets of panels with field generating electrodes such as a pixel electrode, a common electrode, and the like and a liquid crystal layer interposed therebetween. The liquid crystal display generates an electric field in the liquid crystal layer by applying voltage to the field generating electrodes, and determines the direction of liquid crystal molecules of the liquid crystal layer by the generated electric field, thus controlling polarization of incident light so as to display images.

Among liquid crystal displays, a vertically aligned mode liquid crystal display, in which liquid crystal molecules are aligned so that long axes thereof are vertical to the upper and lower panels while the electric field is not applied, has been in the limelight because a contrast ratio is large and a wide reference viewing angle is easily implemented.

In such a vertically aligned mode liquid crystal display, in order to implement a wide viewing angle, a plurality of domains having different alignment directions of the liquid crystal may be formed in one pixel.

As such, as a means of forming the plurality of domains, a method of forming cutouts such as minute slits in the field generating electrode or forming protrusions on the field generating electrode are used. According to the method, the plurality of domains may be formed by aligning the liquid crystal in a vertical direction to the fringe field by edges of the cutouts or the protrusions and a fringe field formed between the field generating electrodes facing the edges.

In the liquid crystal display, a region in which a gate conductor exists is blocked by a black matrix. This directly influences transmittance of the liquid crystal display. Accordingly, in order to increase transmittance of the liquid crystal display, it is important to reduce a size of the region where the gate conductor is formed.

The above information disclosed in this Background section is only for enhancement of understanding of the background of the invention and therefore it may contain information that does not form the prior art that is already known by a person of ordinary skill in the art.

### SUMMARY

Embodiments of the present invention provide a thin film transistor array panel and a liquid crystal display reducing the number of gate conductors and increasing an opening region by disposing a shielding electrode on a data line and shielding a data field by the shielding electrode.

An exemplary embodiment of the present invention provides a thin film transistor array panel, including: a first substrate; a gate conductor on the first substrate; a data conductor on the gate conductor; a shielding electrode on the data conductor and insulated from the data conductor; a passivation layer on the shielding electrode; and a pixel electrode on the passivation layer, in which the shielding electrode includes a vertical portion vertically extending along an edge of a pixel area defined by one pixel electrode and overlapped with the data line, and one or more horizontal portions connecting the vertical portions.

The gate conductor may include a first gate line extending in a horizontal direction, first storage electrode fines horizontally positioned above and below the first gate line, second storage electrode lines horizontally positioned at upper and lower edges of the pixel area, and third storage electrode lines vertically positioned at the center of the pixel area, based on one pixel area.

The shielding electrode may be partially overlapped with the pixel electrode.

The shielding electrode may be never overlapped with the pixel electrode.

The shielding electrode may be made of a transparent conductive material such as ITO or IZO or a reflective metal such as aluminum, silver, chromium, or an alloy thereof.

The vertical portion of the shielding electrode may shield a data field.

Another exemplary embodiment of the present invention provides a thin film transistor array panel, including: a first substrate; a gate conductor on the first substrate; a data conductor on the gate conductor; a shielding electrode on the data conductor and insulated from the data conductor; a passivation layer on the shielding electrode; and a pixel electrode on the passivation layer, in which the shielding electrode includes a vertical portion vertically extending along an edge of a pixel area defined by one pixel electrode and overlapped with the data line, and one or more horizontal portions connecting the vertical portions, and the gate conductor includes a first gate line extending in a horizontal direction, second storage electrode lines horizontally positioned at upper and lower edges of the pixel area, and third storage electrode lines vertically positioned at the center of the pixel area, based on one pixel area.

The shielding electrode may be partially overlapped with the pixel electrode.

The shielding electrode may be made of a transparent conductive material such as ITO or IZO or a reflective metal such as aluminum, silver, chromium, or an alloy thereof.

The vertical portion of the shielding electrode may shield a data field, and the horizontal portion may serve to block light.

Yet another exemplary embodiment of the present invention provides a thin film transistor array panel, including: a first substrate; a gate conductor on the first substrate; a data conductor on the gate conductor; a shielding electrode on the data conductor and insulated from the data conductor; a passivation layer on the shielding electrode; and a pixel electrode on the passivation layer, in which the shielding electrode includes a vertical portion vertically extending along an edge of a pixel area defined by one pixel electrode and overlapped with the data line, and one or more horizontal portions connecting the vertical portions, and the gate conductor includes a first gate line extending in a horizontal direction, second storage electrode lines horizontally positioned at upper and lower edges of the pixel area, third storage electrode lines vertically positioned at the center of the pixel area, based on one pixel area, and one or more floating gate patterns positioned in a region where the pixel electrode and the shielding electrode are overlapped with each other.

The floating gate pattern may indicate a repair point.

The vertical portion of the shielding electrode may shield a data field, and the horizontal portion may serve to block light.

The shielding electrode may be made of a transparent conductive material such as ITO or IZO or a reflective metal such as aluminum, silver, chromium, or an alloy thereof.

Another exemplary embodiment of the present invention provides a method of manufacturing a thin film transistor array panel, including: forming a gate conductor on a substrate; forming a gate insulating layer on the gate conductor; forming a semiconductor, ohmic contacts, and a data conductor on the gate insulating layer; forming a passivation layer on the data conductor; forming a shielding electrode including a vertical portion vertically extending along an edge of a pixel area and overlapped with the data line, and one or more horizontal portions connecting the vertical portions, on the passivation layer; forming a second passivation layer on the shielding electrode; and forming a pixel electrode on the second passivation layer.

The shielding electrode may be made of a transparent conductive material such as ITO or IZO or a reflective metal such as aluminum, silver, chromium, or an alloy thereof.

The gate conductor may include a first gate line extending in a horizontal direction, first storage electrode lines horizontally positioned above and below the first gate line, second storage electrode lines horizontally positioned at upper and lower edges of the pixel area, and third storage electrode lines vertically positioned at the center of the pixel area, based on one pixel area.

An exemplary embodiment of the present invention provides a liquid crystal display, including: a first substrate; a gate conductor on the first substrate; a data conductor on the gate conductor; a shielding electrode on the data conductor; a passivation layer on the shielding electrode; a pixel electrode on the passivation layer; a second substrate; a black matrix on the second substrate; a common electrode on the black matrix; and a liquid crystal formed between the first substrate and the second substrate, in which the shielding electrode includes a vertical portion vertically extending along an edge of a pixel area defined by one pixel electrode and overlapped with the data line, and one or more horizontal portions connecting the vertical portions.

Another exemplary embodiment of the present invention provides a liquid crystal display, including: a first substrate; a gate conductor on the first substrate; a data conductor on the gate conductor; a shielding electrode on the data conductor; a passivation layer on the shielding electrode; a pixel electrode on the passivation layer; a second substrate; a common electrode on the second substrate; and a liquid crystal layer formed between the first substrate and the second substrate, in which the shielding electrode includes a vertical portion vertically extending along an edge of a pixel area defined by one pixel electrode and overlapped with the data line, and one or more horizontal portions connecting the vertical portions.

The same voltage as the common electrode may be applied to the shielding electrode.

As set forth above, in the liquid crystal display according to the present invention, by shielding a data field by a shielding electrode disposed on the data line, an opening region is increased by removing the gate conductor parallel with the data line. Further, the opening region is increased by replacing a gate conductor laterally existing in a pixel area with a shielding electrode and removing the gate conductor.

### BRIEF DESCRIPTION OF THE DRAWINGS

FIG. 1 is a layout view of a thin film transistor array panel according to an exemplary embodiment of the present invention.

FIG. 2 is a cross-sectional view of a liquid crystal display including the thin film transistor array panel of FIG. 1 taken along line II-II.

FIG. 3 is a cross-sectional view of the liquid crystal display including the thin film transistor array panel of FIG. 1 taken along line III-III.

FIG. 4 is a cross-sectional view of a liquid crystal display according to another exemplary embodiment of the present invention.

FIG. 5 is a layout view of a thin film transistor array panel according to another exemplary embodiment of the present invention.

FIG. 6 is a cross-sectional view of the liquid crystal display including the thin film transistor array panel of FIG. 5 taken along line II-II.

FIG. 7 is a layout view of a thin film transistor array panel according to a Comparative Example.

FIG. 8 is a cross-sectional view of the liquid crystal display including the thin film transistor array panel of FIG. 7 taken along line II-II.

FIG. 9 is a layout view of a thin film transistor array panel according to another exemplary embodiment of the present invention.

FIG. 10 is a cross-sectional view of the thin film transistor array panel of FIG. 9 taken along line X-X.

FIG. 11 is a layout view illustrating a thin film transistor array panel according to another exemplary embodiment of the present invention.

FIGS. 12 to 15 illustrate a manufacturing method of a thin film transistor array panel according to an exemplary embodiment of the present invention.

FIG. 16 illustrates a basic electrode of the present invention.

### DETAILED DESCRIPTION

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

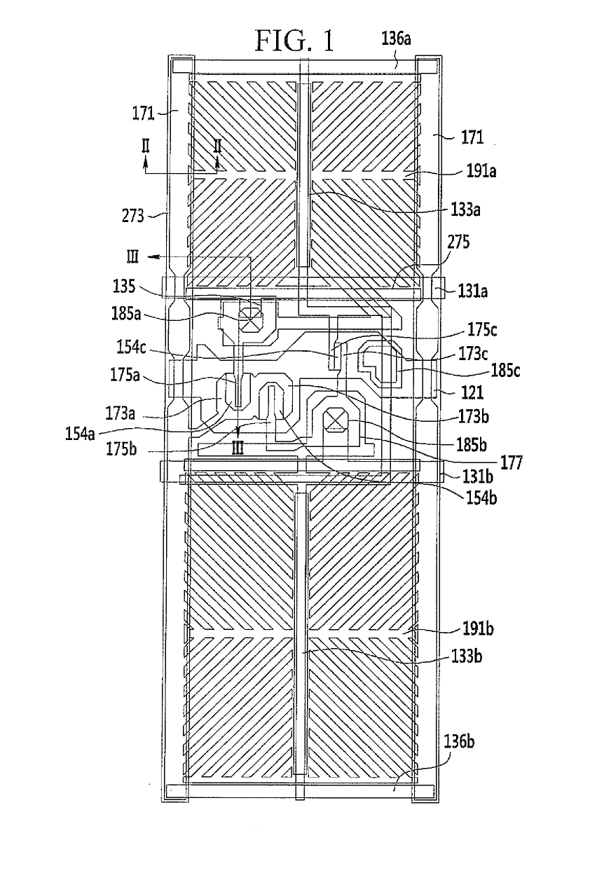

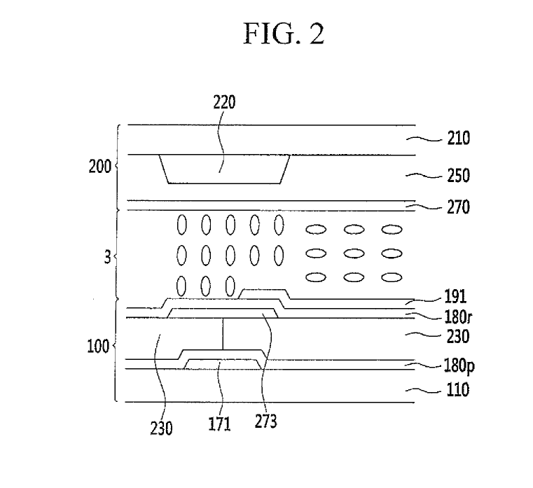

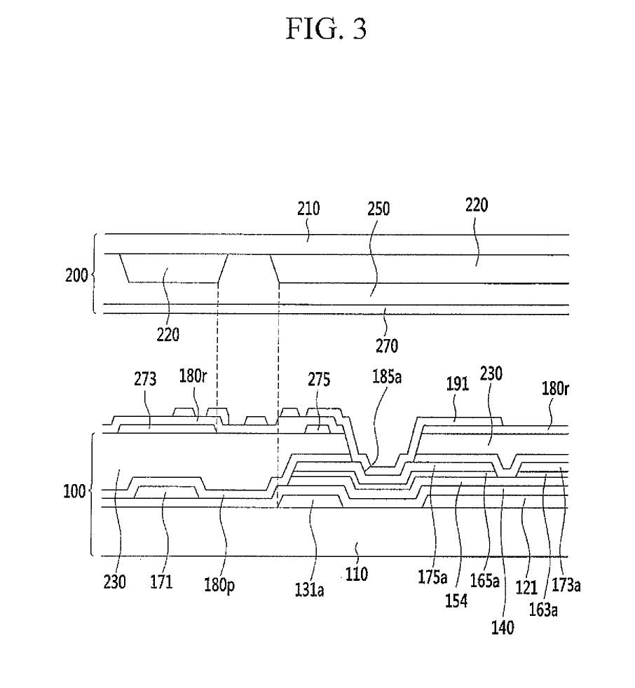

First, structure of a thin film transistor array panel and a liquid crystal display according to an exemplary embodiment of the present invention will be described in brief with reference to FIGS. 1 to 3. FIG. 1 is a layout view of a thin film transistor array panel according to an exemplary embodiment of the present invention, and FIG. 2 is a cross-sectional view of a liquid crystal display including the thin film transistor array panel of FIG. 1 taken along line II-II. FIG. 3 is a cross-sectional view of the liquid crystal display including the thin film transistor array panel of FIG. 1 taken along line III-III.

First, the lower panel 100 will be described.

A gate conductor is formed on an insulation substrate 110 made of transparent glass, plastic, or the like. The gate conductor includes a first gate line 121 extending in a horizontal direction in a pixel area, first storage electrode lines 131a and 131b horizontally positioned above and below the first gate line, second storage electrode lines 136a and 136b horizontally positioned above and below an edge of the pixel area, and third storage electrode lines 133a and 133b vertically positioned at the center of the pixel area. The third storage electrode lines 133a and 133b are not connected with other storage electrode lines, but isolated at the center of the pixel area. That is, the third storage electrode lines are separated from other storage electrode lines to be formed in an island shape.

The term “pixel area” used in the present invention means a pixel unit defined by one pixel electrode 191. FIG. 1 illustrates one pixel area.

A gate insulating layer 140 is formed on the gate line 121 and the storage electrode lines 131a and 131b.

A first semiconductor 154a, a second semiconductor 154b, and a third semiconductor 154c are formed on the gate insulating layer 140.

A plurality of ohmic contacts 163a, 165a, 163b, 165b, 163c, and 165c may be formed on the semiconductors 154a, 154b, and 154c.

A data conductor including a plurality of data lines 171 including a first source electrode 173a and a second source electrode 173b, a first drain electrode 175a, a second drain electrode 175b, a third source electrode 173c, a third drain electrode 175c is formed on the ohmic contacts 163a, 165a, 163b, 165b, 163c, and 165c and the gate insulating layer 140.

The data conductor, the semiconductor positioned below the data conductor, and the ohmic contacts may be simultaneously formed by using one mask.

The data line 171 includes a wide end portion (not illustrated) for connection with another layer or an external driving circuit.

The first gate electrode 124a, the first source electrode 173a and the first drain electrode 175a form a first thin film transistor (TFT) Qa together with the first semiconductor 154a, and a channel of the first thin film transistor is formed in the semiconductor 154a between the first source electrode 173a and the first drain electrode 175a. Similarly, the second gate electrode 124b, the second source electrode 173b, and the second drain electrode 175b form a second thin film transistor Qb together with the second semiconductor 154b, and a channel is formed in the semiconductor 154b between the second source electrode 173b and the second drain electrode 175b. The third gate electrode 124c, the third source electrode 173c, and the third drain electrode 175c form a third thin film transistor Qc together with the third semiconductor 154c, and a channel is formed in the semiconductor 154c between the third source electrode 173c and the third drain electrode 175c.

The second drain electrode 175b includes an extension 177 connected to the third source electrode 173c and widely extended.

On the data conductors (e.g., data lines or electrodes) 171, 173c, 175a, 175b, and 175c and the exposed portion of the semiconductors 154a, 154b, and 154c, a first passivation layer 180p is formed. The first passivation layer 180p may include an inorganic insulating layer made of silicon nitride, silicon oxide, or the like. The first passivation layer 180p may prevent a pigment of the color filter 230 from flowing into the exposed portion of the semiconductors 154a, 154b, and 154c.

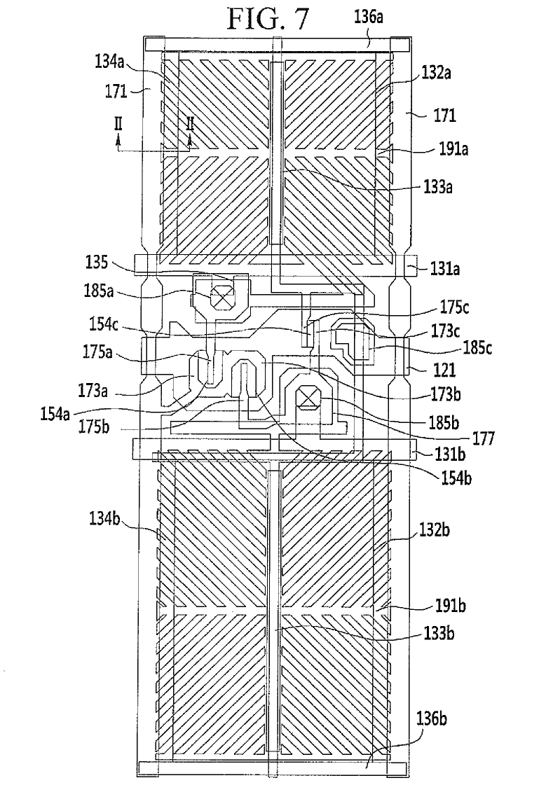

The color filter 230 is formed on the first passivation layer 180p. The color filter 230 extends in a vertical direction along two adjacent data lines. A shielding electrode 273 is formed on the first passivation layer 180p, an edge of the color filter 230, and the data line 171. The shielding electrode 273 is positioned at both sides on the data line 171 along the edge of one pixel area. The shielding electrode 273 includes vertical portions positioned on both edges of the pixel area and a horizontal portion connecting the vertical portions. The horizontal portion may be one or more. Horizontal portions 275 of the shielding electrode are positioned on the first storage electrode lines 131a and 131b (FIG. 7), respectively. The shielding electrodes are not separated from each other for every pixel area, but are connected to the entire adjacent pixels to be integrally formed. That is, since the vertical portions of the shielding electrode at the both edges and one or more horizontal portions connecting the vertical portions exist for every pixel area, the shielding electrodes have a mesh form in all the pixels.

The shielding electrode 273 may be made of a transparent conductive material such as indium tin oxide (ITO) or indium zinc oxide (IZO), or a reflective metal such as aluminum, silver, chromium, or an alloy thereof. The horizontal portions 275 of the shielding electrode may be made of the same material as the shielding electrode 273, or different materials from the shielding electrode 273.

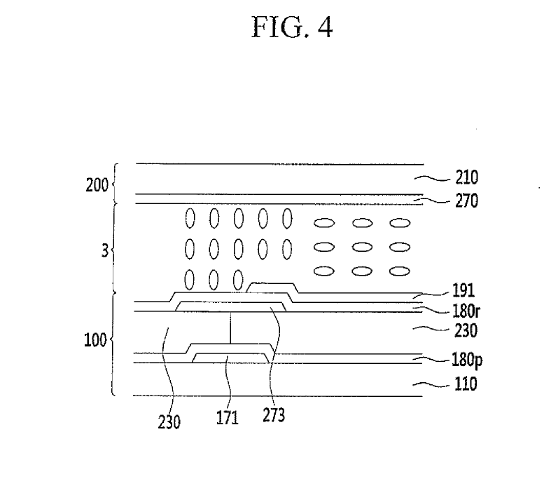

The same voltage as the common electrode 270 is applied to the shielding electrode 273, and coupling between the data line and the pixel electrode is blocked by the shielding electrode. Since the same voltage is applied to the shielding electrode and the common electrode, an electric field is not generated between the shielding electrode and the common electrode, and a liquid crystal layer positioned therebetween is not aligned. Accordingly, a liquid crystal between the shielding electrode and the common electrode becomes black. As such, in the case where the liquid crystal is black, the liquid crystal itself may serve as a black matrix. Accordingly, in the liquid crystal display according to the exemplary embodiment of the present invention, as illustrated in FIG. 4, a black matrix of the upper panel may be removed. In FIG. 4, the liquid crystal between the shielding electrode and the common electrode serves as the black matrix.

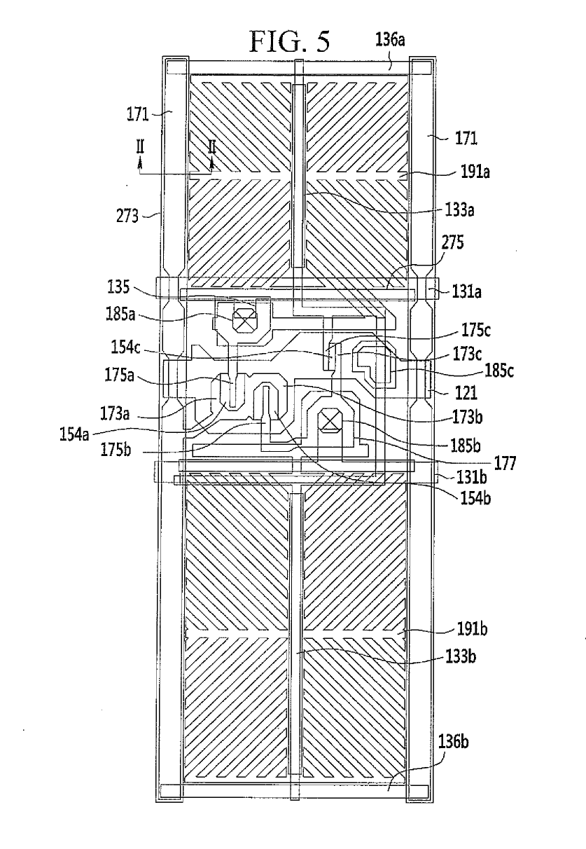

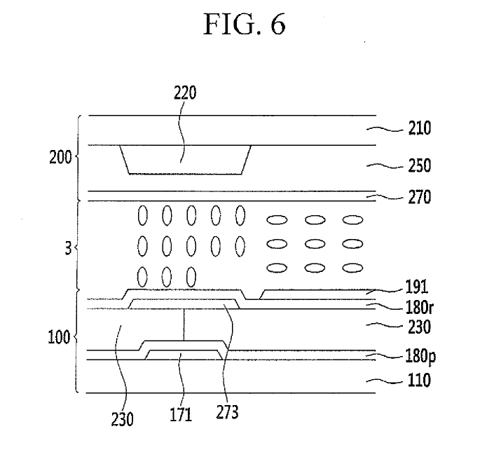

The shielding electrode 273 may be partially overlapped with the pixel electrode 191 as illustrated in FIGS. 1 to 4, and may not be nearly overlapped with the pixel electrode as illustrated in FIGS. 5 and 6. When the shielding electrode 273 is partially overlapped with the pixel electrode 191, an overlapped area may be half or less of the entire area of the shielding electrode 273. The shielding electrode 273 includes vertical portions overlapped with an edge data line of one pixel area and one or more horizontal portions connecting the vertical portions. Two horizontal portions may be positioned above and below the gate line 121, that is, at respective positions overlapped with the third storage electrode lines 133a and 133b. That is, the shielding electrode may exist in a trapezoid shape having two vertical lines and two horizontal lines connecting the two vertical lines in one pixel area.

The shielding electrode may be divided into an upper region positioned above the upper horizontal line, a middle region positioned between the upper and lower horizontal lines, and a lower region positioned below the lower horizontal line. In this case, the pixel electrode contacts the drain electrode in the middle region of the shielding electrode, and one first subpixel electrode 191a is positioned in the upper region, and a second subpixel electrode 191b is positioned in the lower region.

In embodiments where the shielding electrode 273 and the pixel electrode 191 are partially overlapped with each other, a minute branch of the pixel electrode 191 and the horizontal portion or the vertical portion of the shielding electrode are positioned on the same vertical line when viewed in cross section. That is, when an imaginary line vertical to the substrate is illustrated at both edges of the horizontal portion or the vertical portion of the shielding electrode, the imaginary line and the pixel electrode meet each other where the imaginary line and the pixel electrode are overlapped with each other. In embodiments where the shielding electrode 273 and the pixel electrode 191 are partially overlapped with each other includes an embodiment where only the horizontal portion of the shielding electrode is overlapped with the pixel electrode, an embodiment where only the vertical portion of the shielding electrode is overlapped with the pixel electrode, and an embodiment where both the horizontal portion and the vertical portion of the shielding electrode are overlapped with the pixel electrode.

In embodiments where the shielding electrode 273 and the pixel electrode 191 are overlapped with each other, since a storage capacitor is increased, a kickback voltage is reduced.

A second passivation layer 180r is formed on the shielding electrode 273. The second passivation layer 180r may include an inorganic insulating layer made of silicon nitride, silicon oxide, or the like. The second passivation layer 180r may prevent the color filter 230 from being lifted, and suppresses contamination of the liquid crystal layer 3 due to an organic material such as a solvent flowing into from the color filter 230 to prevent defects such as an afterimage which may be caused when a screen is driven.

In the first passivation layer 180p and the second passivation layer 180r, a first contact hole 185a and a second contact hole 185b exposing the first drain electrode 175a and the second drain electrode 175b are formed.

A plurality of pixel electrodes 191 is formed on the second passivation layer 180r. The shielding electrode and the pixel electrode are electrically insulated from each other by the second passivation layer. Each pixel electrode 191 includes the first subpixel electrode 191a and the second subpixel electrode 191b which are separated from each other with the gate line 121 therebetween to be adjacent to each other in a column direction based on the gate line 121. The pixel electrode 191 may be made of a transparent material such as ITO or IZO. The pixel electrode 191 may also be made of a reflective metal such as aluminum, silver, chromium, or an alloy thereof.

The whole shape of the first subpixel electrode 191a and second subpixel electrode 191b is a quadrangle, and includes a cross stem including a horizontal stem and a vertical stem perpendicular to the horizontal stem.

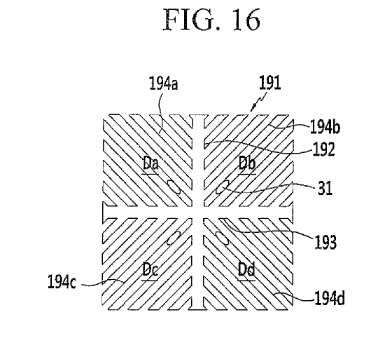

The third storage electrode lines 133a and 133b are positioned to be overlapped with the vertical stems of the first subpixel electrode 191a and the second subpixel electrode 191b, respectively. However, the third storage electrode lines have an isolated form, and do not meet the first storage electrode lines 131a and 131b or the second storage electrode lines 136a and 136b. That is, a length of the third storage electrode line is smaller than a vertical length of an area occupied by one subpixel electrode. A width of the third storage electrode line may be larger or smaller than the horizontal stem of the subpixel electrode. The first subpixel electrode 191a and the second subpixel electrode 191b each include a basic electrode 199 illustrated in FIG. 16 or one or more modifications.

The first subpixel electrode 191a and the second subpixel electrode 191b are physically and electrically connected to the first drain electrode 175a and the second drain electrode 175b through the first contact hole 185a and the second contact hole 185b, respectively, and receive data voltages from the first drain electrode 175a and the second drain electrode 175b. In this embodiment, a part of the data voltage applied to the second drain electrode 175b is divided through the third source electrode 173c, and as a result, a magnitude of the voltage applied to the first subpixel electrode 191a may be larger than a magnitude of the voltage applied to the second subpixel electrode 191b.

The first subpixel electrode 191a and the second subpixel electrode 191b to which the data voltages are applied generate an electric field together with a common electrode 270 of the upper panel 200 to determine directions of the liquid crystal molecules of the liquid crystal layer 3 between the two electrodes 191 and 270. Luminance of light passing through the liquid crystal layer 3 varies according to the determined directions of the liquid crystal molecules.

Next, the upper panel 200 will be described.

A light blocking member 220 is formed on an insulation substrate 210 made of transparent glass, plastic, or the like. The light blocking member 220 is also called a black matrix and blocks light leakage.

The black matrix 220 is formed to cover the entire region where the first transistor Qa, the second transistor Qb, and the third transistor Qc of the lower panel 100, and the first to third contact holes 185a, 185b, and 185c are positioned, and extends in the same direction as the gate fine 121 to be overlapped with a part of the data line 171. The black matrix is positioned to be overlapped with at least a part of the two data lines 171 positioned at both sides of one pixel area to prevent light leakage which may occur around the data line 171 and the gate line 121, and may prevent light leakage in the region where the first transistor Qa, the second transistor Qb, and the third transistor Qc are positioned.

An overcoat 250 is formed on the black matrix 220. The overcoat 250 may be made of an (organic) insulator, and provides a flat surface. The overcoat 250 may be omitted. The common electrode 270 is formed on the overcoat.

An upper alignment layer (not illustrated) is formed on the common electrode 270. The upper alignment layer may be a vertical alignment layer.

The liquid crystal layer 3 has negative dielectric anisotropy, and the liquid crystal molecules of the liquid crystal layer 3 are aligned so that long axes thereof are vertical to the surfaces of the two panels 100 and 200 without applying an electric field.

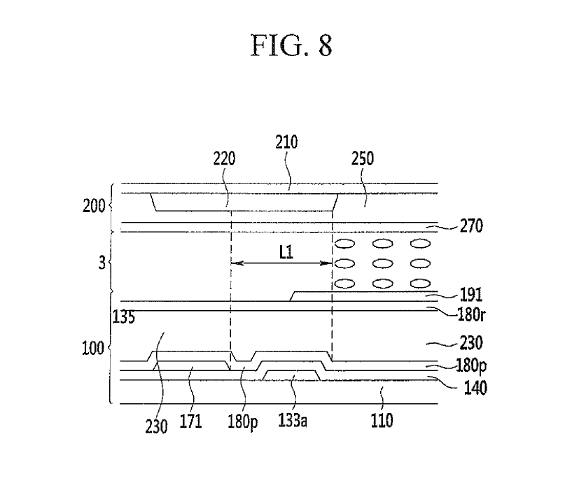

FIG. 7 is a layout view of a thin film transistor array panel according to a Comparative Example, and FIG. 8 is a cross-sectional view of the liquid crystal display including the thin film transistor array panel of FIG. 7 taken along line II-II. As illustrated in FIG. 7, in the case of an existing thin film transistor array panel, fourth storage electrode lines 132a, 132b, 134a, and 134b are parallel with the data line 171 are positioned. This is to prevent coupling of the data line 171 and the pixel electrode 191, and the fourth storage electrode lines 132a, 132b, 134a, and 134b are made of the same material as the gate line and serve to shield the data voltage.

In this embodiment, the black matrix 220 is disposed to block the data line 171 and the fourth storage electrode line 134a as illustrated in FIG. 8. That is, the black matrix needs to be formed larger than an embodiment where the fourth storage electrode line does not exist by L1. This is one cause of reducing an aperture ratio of the thin film transistor array panel.

However, the present invention prevents the coupling of the data line 171 and the pixel electrode 191 by forming the shielding electrode 273 on the data line 171 and expands the opening region by removing the fourth storage electrode lines 132a, 132b, 134a, and 134b parallel to the data line. That is, in the existing structure, the black matrix 220 needs to be positioned up to on the fourth storage electrode lines 132a, 132b, 134a, and 134b, while in the thin film transistor array panel of the present invention, when the black matrix 220 is positioned only on the data line 171, the opening region is increased.

Next, the basic electrode 199 will be described with reference to FIG. 16.

As illustrated in FIG. 16, an overall shape of the basic electrode 199 is a quadrangle, and includes a cross stem configured by a horizontal stem 193 and a vertical stem 192 perpendicular to the horizontal stem 193. Further, the basic electrode 199 is divided into a first subregion Da, a second subregion Db, a third subregion Dc, and a fourth subregion Dd by the horizontal stem 193 and the vertical stem 192, and the respective subregions Da to Dd include a plurality of first minute branches 194a, a plurality of second minute branches 194b, a plurality of third minute branches 194c, and a plurality of fourth minute branches 194d.

The first minute branches 194a obliquely extend in an upper left direction from the horizontal stem 193 or the vertical stem 192, and the second minute branches 194b obliquely extend in an upper right direction from the horizontal stem 193 or the vertical stem 192. Further, the third minute branches 194c obliquely extend in a lower left direction from the horizontal stem 193 or the vertical stem 192, and the fourth minute branches 194d obliquely extend in a lower right direction from the horizontal stem 193 or the vertical stem 192.

The first to fourth minute branches 194a, 194b, 194c, and 194d may form an angle of approximately 45° or 135° with the gate lines 121a and 121b or the horizontal stem 193. Further, the minute branches 194a, 194b, 194c, and 194d of two adjacent subregions Da, Db, Dc, and Dd may be perpendicular to each other.

Widths of the minute branches 194a, 194b, 194c, and 194d may be 2.5 μm to 5.0 μm, and a distance between the adjacent minute branches 194a, 194b, 194c, and 194d in one of the subregions Da, Db, Dc, and Dd may be 2.5 μm to 5.0 μm.

According to another exemplary embodiment of the present invention, widths of the minute branches 194a, 194b, 194c, and 194d may be increased toward the horizontal stem 193 or the vertical stem 192, and a difference between the largest portion and the smallest portion of the width of one of the minute branches 194a, 194b, 194c, and 194d may be 0.2 μm to 1.5 μm.

The first subpixel electrode 191a and the second subpixel electrode 191b are connected to the first drain electrode 175a or the second drain electrode 175b through the first contact hole 185a and the second contact hole 185b, respectively, and receive data voltages from the first drain electrode 175a and the second drain electrode 175b. In this case, sides of the first to fourth minute branches 194a, 194b, 194c, and 194d distort the electric field to make horizontal components which determine tilt directions of the liquid crystal molecules 31. The horizontal components of the electric field are substantially parallel to the sides of the first to fourth minute branches 194a, 194b, 194c, and 194d. Accordingly, the liquid crystal molecules are tilted in a direction parallel to a longitudinal direction of the minute branches 194a, 194b, 194c, and 194d. Since one pixel electrode 191 includes the four subregions Da to Dd in which longitudinal directions of the minute branches 194a, 194b, 194c, and 194d are different from each other, the tilt directions of the liquid crystal molecules 31 are approximately four, and four domains D1 to D4 in which alignment directions of the liquid crystal molecules 31 are different from each other are formed in the liquid crystal layer 3. As such, a reference viewing angle of the liquid crystal display may be increased by varying the tilt directions of the liquid crystal molecules 31.

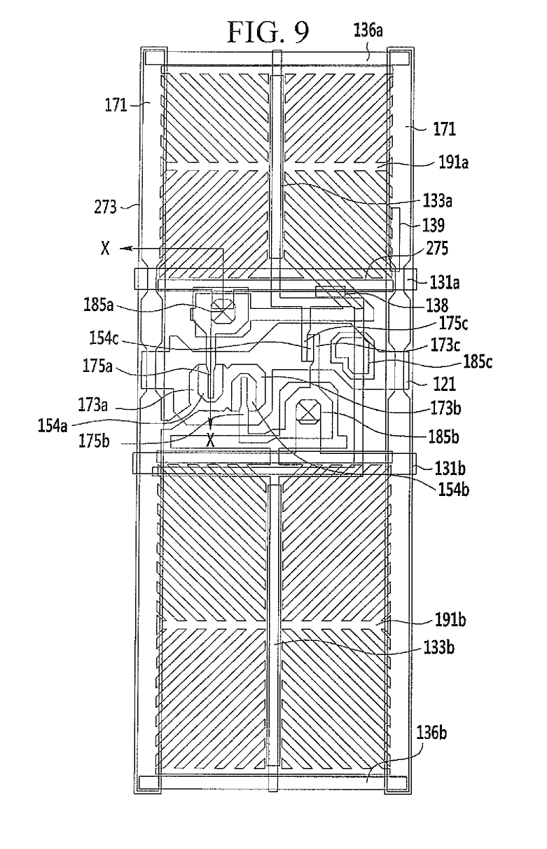

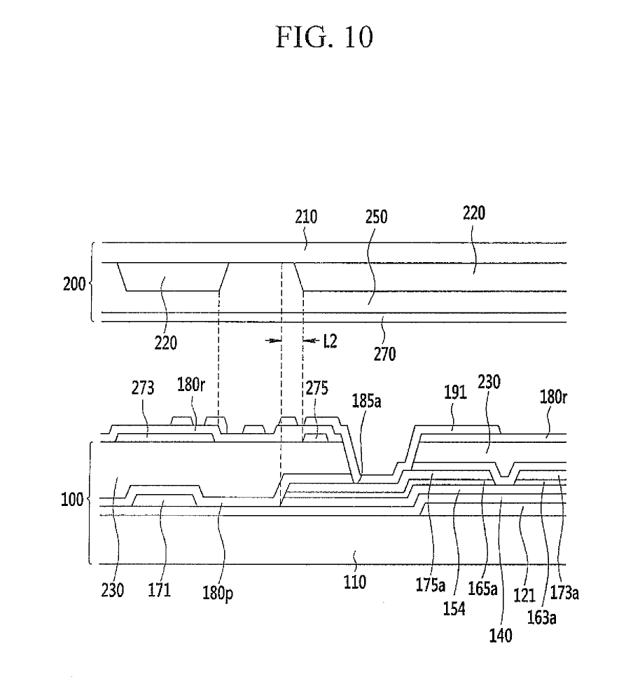

Next, a thin film transistor array panel according to another exemplary embodiment of the present invention will be described with reference to FIGS. 9 and 10. Referring to FIGS. 9 and 10, the thin film transistor array panel according to the exemplary embodiment is similar to the thin film transistor array panel in FIG. 1. The detailed description for like constituent elements is omitted.

However, in the thin film transistor array panel according to the exemplary embodiment, unlike the thin film transistor array panel according to the exemplary embodiment illustrated in FIG. 1, the first storage electrode lines 131a and 131b are omitted. That is, the horizontal portion 275 connecting the shielding electrodes 273 which exist at the edge of the pixel area serves as the existing first storage electrode line. The shielding electrode 273 and the horizontal portion 275 serve to block the gate field and replace a light blocking role of the first storage electrode lines 131a and 131b. Accordingly, the first storage electrode lines 131a and 131b may be removed. In the existing structure, the black matrix 220 may be positioned up to on the first storage electrode lines 131a and 131b, while in the liquid crystal display according to the exemplary embodiment, since the black matrix 220 may be positioned up to on the horizontal portion 275 of the shielding electrode, the aperture ratio is increased.

FIG. 10 is a cross-sectional view of the liquid crystal display of FIG. 9 taken along line X-X. As illustrated in FIG. 10, the black matrix 220 is positioned to correspond to the upper portion of the horizontal portion 275 of the shielding electrode. Accordingly, as compared with the existing case where the storage electrode lines 131a and 131b exist, the opening region may be further expanded by L2.

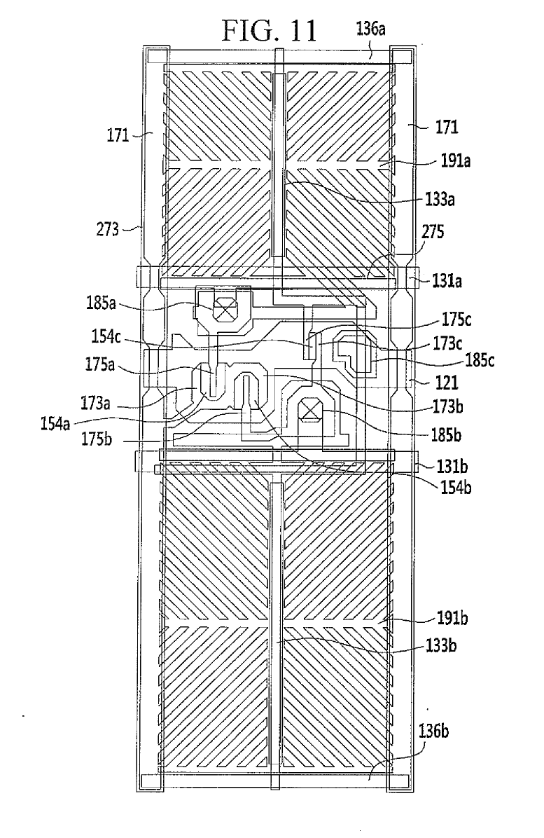

Next, a liquid crystal display according to another exemplary embodiment of the present invention will be described with reference to FIG. 11. Referring to FIG. 11, the liquid crystal display according to the exemplary embodiment is similar to the liquid crystal display according to the exemplary embodiment illustrated in FIG. 9. The detailed description for like constituent elements is omitted.

However, the liquid crystal display according to the exemplary embodiment further includes floating gate patterns 138 (FIG. 9) and 139 (FIG. 9). The floating gate pattern 139 may be lengthily positioned in a vertical direction along a shielding electrode 273 below the horizontal portion 275 and the pixel electrode 191, or the floating gate pattern 138 may be positioned in a horizontal direction below the horizontal portion 275 of the shielding electrode and the pixel electrode 191. Only one or two of the floating gate patterns 138 and 139 may exist, and a plurality of floating gate patterns may exist in any region where the shielding electrode 273 and pixel electrode 191 are overlapped with each other.

The floating gate pattern serves to indicate a repair point. That is, when both the shielding electrode 273 and pixel electrode 191 are made of transparent conductive materials, it is difficult to find the repair point. As illustrated in FIG. 7, in the liquid crystal display with the existing first storage electrode lines 131a and 131b, a protrusion 135 of the first storage electrode line serves to indicate the repair point. However, as illustrated in FIG. 9, in the liquid crystal display according to the exemplary embodiment of the present invention in which the first storage electrode line is removed, the repair point is not indicated. Accordingly, the floating gate patterns 138 and 139 are disposed in the region where the shielding electrode and pixel electrode are overlapped with each other, thereby indicating the repair point. The positions and the shapes of the floating gate patterns are not limited to the drawing illustrated in the present invention, and a plurality of floating gate patterns may be formed without limit in any region where the shielding electrode 273 and pixel electrode 191 are overlapped with each other.

As illustrated in FIG. 9, when the floating gate pattern 139 is vertically positioned parallel with a shielding electrode 273, since the floating gate pattern 139 is lengthwise overlapped with the pixel electrode 191, a repair range is large and the repair is easy.

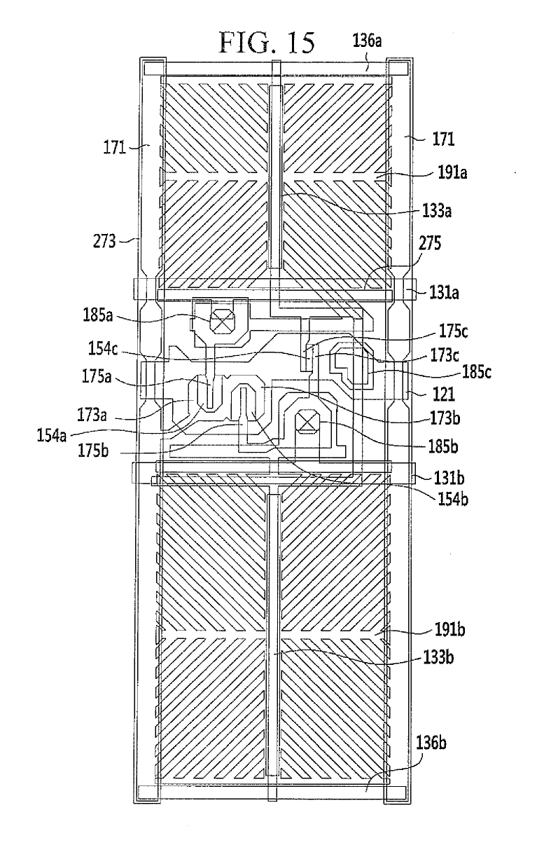

Next, a manufacturing method of a thin film transistor array panel according to an exemplary embodiment of the present invention will be described with reference to FIGS. 3, and 12 to 15.

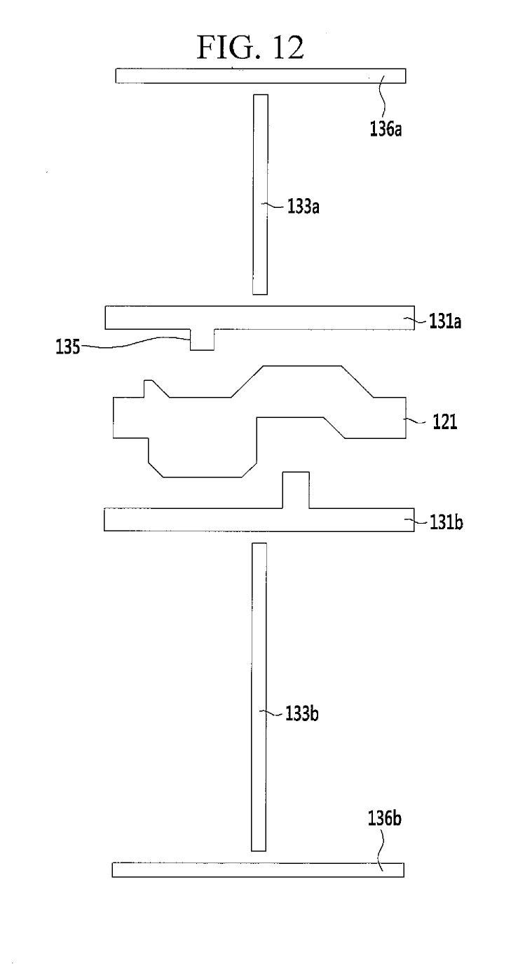

First, as illustrated in FIG. 12, a gate conductor is formed on an insulation substrate 110 (FIG. 3) made of transparent glass, plastic, or the like. The gate conductor includes a first gate line 121 extending in a horizontal direction, first storage electrode lines 131a and 131b horizontally positioned above and below the first gate line, second storage electrode lines 136a and 136b horizontally positioned at upper and lower edges of the pixel area, and third storage electrode lines 133a and 133b vertically positioned at the center of the pixel area, based on one pixel area. The first storage electrode line has a protrusion 135 for repairing.

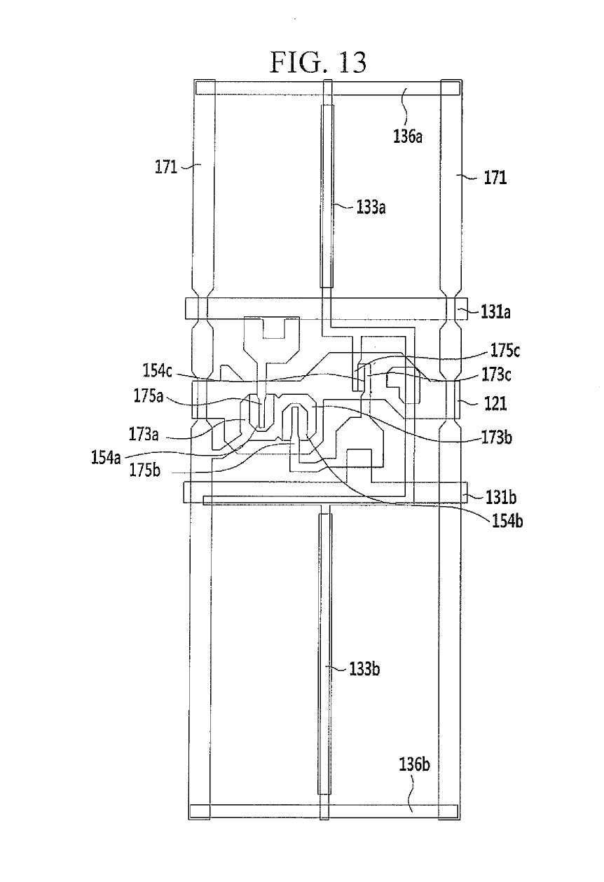

Next, as illustrated in FIG. 13, a gate insulating layer is formed on the gate conductor, and then a data conductor is formed. A semiconductor and ohmic contacts are formed below the data conductor, and may be simultaneously formed by using one mask. The data conductor includes a data line 171 extending along both edges of the pixel area, a source electrode, and a drain electrode. The source electrode and the drain electrode, and a semiconductor channel positioned therebetween form one thin film transistor, and a total of three thin film transistors are formed in the pixel area.

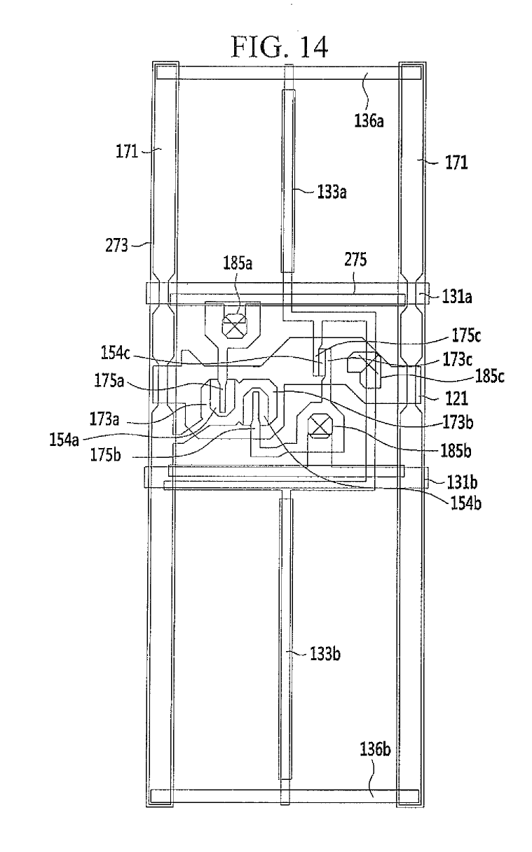

Next, as illustrated in FIG. 14, a first passivation layer and a color filter are sequentially laminated on the data conductor and the semiconductor, and then a shielding electrode 273 is formed thereon. The shielding electrode is parallel with the data line 171, and includes a horizontal portion 275 connecting shielding electrodes positioned on opposite sides. The horizontal portion 275 is horizontally positioned parallel with the first storage electrode lines 131a and 131b, and closer to the gate line 121 than the first storage electrode lines 131a and 131b.

Next, as illustrated in FIG. 10, a second passivation layer 180r is formed on the shielding electrode, and then a pixel electrode 191 is formed on the second passivation layer. The pixel electrode 191 is electrically insulated from the shielding electrode through the second passivation layer, and the pixel electrodes 191a and 191b are physically and electrically connected with the drain electrode through the contact holes 185a and 185b formed in the first passivation layer and the second passivation layer.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

Description of symbols

| 110, 210: Insulation substrate | |
|---|---|
| 3: Liquid crystal layer | |
| 121: Gate line | |
| 124: Gate electrode | |
| 131, 132, 133, 134, 136: Storage electrode line | |
| 138, 139: Floating gate pattern | |
| 140: Gate insulating layer | |
| 154: Semiconductor | |
| 163, 165: Ohmic contact | |
| 171: Data line | |
| 173: Source electrode | |
| 175: Drain electrode | |
| 180p, 180r: Passivation layer | |
| 185: Contact hole | |
| 191: Pixel electrode | 220: Light blocking member |
| 230: Color filter | 250: Overcoat |

270: Common electrode
273: Shielding electrode

What is claimed is:

1. A thin film transistor array panel, comprising:
a first substrate;
a gate conductor on the first substrate;
a data conductor on the gate conductor;
a shielding electrode on the data conductor and insulated from the data conductor;
a passivation layer on the shielding electrode; and
a pixel electrode on the passivation layer,
wherein the shielding electrode includes a vertical portion vertically extending along an edge of a pixel area defined by one pixel electrode and overlapped with a data line, and one or more horizontal portions connecting the vertical portions.

2. The thin film transistor array panel of claim 1, wherein:
the gate conductor includes a first gate line extending in a horizontal direction, first storage electrode lines horizontally positioned above and below the first gate line, second storage electrode lines horizontally positioned at upper and lower edges of the pixel area, and third storage electrode lines vertically positioned at the center of the pixel area, based on one pixel area.

3. The thin film transistor array panel of claim 1, wherein:
the shielding electrode is partially overlapped with the pixel electrode.

4. The thin film transistor array panel of claim 1, wherein:
the shielding electrode is never overlapped with the pixel electrode.

5. The thin film transistor array panel of claim 1, wherein:
the shielding electrode is made of a transparent conductive material such as ITO or IZO or a reflective metal such as aluminum, silver, chromium, or an alloy thereof.

6. The thin film transistor array panel of claim 1, wherein:
the vertical portion of the shielding electrode shields a data field.

7. The thin film transistor array panel of claim 2, wherein:
the first storage electrode lines horizontally positioned above and below the first gate line are not included.

8. The thin film transistor array panel of claim 7, wherein:
the shielding electrode is partially overlapped with the pixel electrode.

9. The thin film transistor array panel of claim 8, wherein:
the shielding electrode is made of a transparent conductive material such as ITO or IZO or a reflective metal such as aluminum, silver, chromium, or an alloy thereof.

10. The thin film transistor array panel of claim 9, wherein:
the vertical portion of the shielding electrode shields a data field, and the horizontal portion serves to block light.

11. The thin film transistor array panel of claim 7, further comprising:
one or more floating gate patterns positioned in a region where the pixel electrode and the shielding electrode are overlapped with each other.

12. The thin film transistor array panel of claim 11, wherein:
the floating gate pattern indicates a repair point.

13. The thin film transistor array panel of claim 11, wherein:
the vertical portion of the shielding electrode shields a data field, and the horizontal portion serves to block light.

14. The thin film transistor array panel of claim 13, wherein:
the shielding electrode is made of a transparent conductive material such as ITO or IZO or a reflective metal such as aluminum, silver, chromium, or an alloy thereof.

15. A method of manufacturing a thin film transistor array panel, comprising:
forming a gate conductor on a substrate;
forming a gate insulating layer on the gate conductor;
forming a semiconductor, ohmic contacts, and a data conductor on the gate insulating layer;
forming a passivation layer on the data conductor;
forming a shielding electrode including a vertical portion vertically extending along an edge of a pixel area and overlapped with a data line, and one or more horizontal portions connecting the vertical portions, on the passivation layer;
forming a second passivation layer on the shielding electrode; and
forming a pixel electrode on the second passivation layer.

16. The method of claim 15, wherein:
the shielding electrode is made of a transparent conductive material such as ITO or IZO or a reflective metal such as aluminum, silver, chromium, or an alloy thereof.

17. The method of claim 15, wherein:
the gate conductor includes a first gate line extending in a horizontal direction, first storage electrode lines horizontally positioned above and below the first gate line, second storage electrode lines horizontally positioned at upper and lower edges of the pixel area, and third storage electrode lines vertically positioned at the center of the pixel area, based on one pixel area.

18. A liquid crystal display, comprising:
a first substrate;
a gate conductor on the first substrate;
a data conductor on the gate conductor;
a shielding electrode on the data conductor and insulated from the data conductor;
a passivation layer on the shielding electrode;
a pixel electrode on the passivation layer;
a second substrate;
a common electrode on the second substrate; and
a liquid crystal formed between the first substrate and the second substrate,
wherein the shielding electrode includes a vertical portion vertically extending along an edge of a pixel area and overlapped with a data line, and one or more horizontal portions connecting the vertical portions.

19. The liquid crystal display of claim 18, wherein:
a black matrix is formed between the second substrate and the common electrode.

20. The liquid crystal display of claim 18, wherein:
the same voltage as the common electrode is applied to the shielding electrode.
